(19) United States
(12) Patent Application Publication
(10) Pub. No.: US 2010/0009469 A1
(43) Pub. Date: Jan. 14, 2010

(54) PLASMA DOPING METHOD AND APPARATUS

(76) Inventors: Takayuki Kai, Kyoto (JP); Tomohiro Okumura, Osaka (JP); Hisao Nagai, Osaka (JP); Cheng-Guo Jin, Osaka (JP); Bunji Mizuno, Nara (JP)

Correspondence Address: MCDERMOTT WILL & EMERY LLP, 600 13TH STREET, NW, WASHINGTON, DC, 20005-3096, US

(21) Appl. No.: 12/398,669

(22) Filed: Mar. 5, 2009

(30) Foreign Application Priority Data
Mar. 5, 2008 (JP) 2008-054726

(51) Int. Cl. H01L 21/02

(52) U.S. Cl. 438/7; 118/708; 257/E21.002

(57) ABSTRACT

During a plasma discharging process, a laser beam having a certain exciting wavelength is applied to a surface of a process substrate, so as to measure, using scattered light, an impurity density and a crystal state on the surface of the process substrate.

### BACKGROUND OF THE INVENTION

The present invention relates to a plasma doping method and a plasma doping apparatus used for introducing an impurity into a process substrate in preparing an electronic device.

As a technique for introducing an impurity into a surface of a solid-state sample, a plasma doping method has been known in which an impurity is ionized and then the ionized impurity is introduced into a solid-state material at low energy (for example, see Patent Document 1). FIG. 13 shows a schematic structure of a plasma processing apparatus used in a plasma doping method serving as a conventional impurity introducing method described in Patent Document 1. In FIG. 13, a sample electrode 206 on which a sample 209 made of a silicon substrate is to be mounted is placed in a vacuum container 201. A gas supply device 202 for supplying a doping material gas containing a desired element, such as B₂H₆, and a pump 203 for reducing the pressure in the vacuum container 201 are placed so that the inside of the vacuum container 201 can be maintained at a predetermined pressure. A microwave is projected by a microwave waveguide tube 219 into the vacuum container 201 through a quartz plate 207 serving as a dielectric window. By an interaction between this microwave and a DC magnetic field formed by an electromagnet 214, a microwave plasma with a magnetic field (electron cyclotron resonance plasma) 220 is formed in the vacuum container 201. A high-frequency power supply 210 is connected to the sample electrode 206 with a capacitor 221 interposed therebetween so as to control the electric potential of the sample electrode 206. The gas supplied from the gas supply device 202 is provided into the vacuum container 201 through a gas supply inlet 211, and is exhausted to the pump 203 through an exhaust outlet 212.

In the plasma processing apparatus having such a structure, the doping material gas such as B₂H₆ supplied through the gas supply inlet 211 is formed into plasma by a plasma generating means constituted by the microwave waveguide tube 219 and the electromagnet 214 so that boron ions in plasma 220 are introduced into the surface of the sample 209 by the high-frequency power supply 210.

Normally, a gate oxide film made of a thermal oxide film or the like is formed on the surface of the sample 209, and a conductive layer to serve as a gate electrode is formed on this layer by the CVD method or the like. This conductive layer is patterned so that a pattern of the gate electrode is formed. The sample 209 with the gate electrode formed thereon in this manner is set in the plasma doping apparatus, and an impurity is introduced thereinto in a self-aligned manner using the gate electrode as a mask in accordance with the above-mentioned method, so that a source-drain region is formed and an MOS transistor is consequently obtained. However, since the transistor is not formed only by introducing the impurity in the plasma doping process, an activating process needs to be carried out. The activating process refers to a process in which a layer having an impurity introduced thereinto is heated in a laser annealing process or a flash lamp annealing process so as to cause an active state in a crystal. In this case, by effectively heating an extremely thin layer having an impurity introduced thereinto, a shallow activated layer can be obtained. In order to effectively heat the extremely thin layer having the impurity introduced thereinto, prior to the introduction of the impurity, the extremely thin layer to have the impurity introduced thereinto is subjected to a process of enhancing the absorbing rate to light to be projected from a light source such as a laser or a lamp. This process is referred to as a pre-amorphous state forming process. In a plasma processing apparatus having a structure similar to that of the above-mentioned plasma processing apparatus, plasma from a He gas or the like is generated, and generated ions of He or the like are accelerated toward a substrate by a bias voltage and collide therewith so that a crystal structure on the substrate surface is damaged to form an amorphous state (formed into an amorphous state) (for example, see Patent Document 4).

On the other hand, a conventional arrangement has been proposed that a high-frequency power is applied from the high-frequency power supply 210 to the sample electrode 206 in the vacuum container 201 so that plasma is generated in the vacuum container 201, and an impedance, a voltage, or a current is monitored at a certain point between the sample electrode 206 and the high-frequency power supply 210 so as to calculate the quantity and the incident energy of ions made incident from the plasma into the process substrate 209 (for example, see Patent Document 2). Based upon these calculated values, the applied amount of power of the microwave, the processing time, and the pressure are feed-back controlled, so that a desired amount and a desired depth of the impurity can be obtained.

Moreover, in order to analyze elements of foreign matters adhering onto the substrate in the plasma processing apparatus, a laser light beam is projected onto the substrate, a deviation in the frequency of scattered light from the substrate is detected, and based upon results of detection, the substance is identified so that a component to be subjected to a maintenance process is identified and the life thereof is consequently calculated (for example, see. Patent Document 3).

Patent Document 1: U.S. Pat. No. 4,912,065

### Patent Document 2: Japanese Published Patent Publication No. 2003-513439

### Patent Document 3: Japanese Unexamined Patent Publication No. 2001-185545

Patent Document 4: International Publication No. WO2005-031832

However, in the conventional method, since the quantity and the incident energy of the ions are indirectly calculated, the quantity and the incident energy of the ions in the doping material gas can not be separated from those in the other gas in the plasma, with the result that, in some cases, the amount of an impurity obtained based on the quantity and the incident energy of the ions thus calculated is not made coincident with an amount of the impurity to be actually injected into the process substrate. For example, in a case shown in FIG. 13 where diborane and helium are supplied into the vacuum container 201 through the gas supply inlet 211, boron ions, helium ions, and other ions are generated in plasma generated in the vacuum container 201, with the result that it is impossible to detect details thereof by monitoring the impedance, the current, the voltage, or the like. It is impossible to completely control the process and is thus impossible to control the amount of the impurity to be injected into the process substrate 209 upon fluctuation in the process.

Therefore, in order to solve the above-mentioned issues, it is an object of the present invention to provide a plasma doping method and a plasma doping apparatus that can accurately control the density of an impurity to be injected into a process substrate.

### SUMMARY OF THE INVENTION

In order to achieve the above-mentioned object, the present invention has the following structures.

According to a first aspect of the present invention, there is provided a plasma doping method comprising: placing a substrate on an electrode in a vacuum chamber; supplying a dopant gas into the vacuum chamber and controlling an inside of the vacuum chamber to a certain fixed pressure so that a plasma is generated therein; and applying a high-frequency power to the substrate and injecting a dopant into a surface of the substrate so that a plasma doping layer is formed, the method comprising:

during a plasma discharging process, to a first region for forming the plasma doping layer on the surface of the substrate, allowing a first laser light beam serving as exciting light with a wavelength corresponding to an light absorption exerted therein, to be made incident in a direction orthogonal to the surface of the substrate;

receiving first scattered light from the substrate at a detector;

spectrum-resolving the first scattered light received by the detector using a spectroscope;

computing the first scattered light at an operation unit based on a spectrum with unnecessary exciting wavelengths having been removed by spectrum division at the spectroscope, and computing an impurity density of the plasma doping layer on the surface of the substrate at the operation unit based on the computed first scattered light; and

while feed-back-controlling plasma processing conditions at a control device so as to allow the computed impurity density to be equal to a set impurity density, injecting the dopant into the surface of the substrate to form the plasma doping layer.

According to a second aspect of the present invention, there is provided the plasma doping method according to the first aspect, wherein a wavelength of an exciting laser light beam having an absorption coefficient corresponding to a thickness of 5 nm to 100 nm of the plasma doping layer to be formed in the substrate is used as the wavelength of the first laser light beam, with the wavelength of the first laser light beam to be used being set to 190 nm to 420 nm.

According to a third aspect of the present invention, there is provided the plasma doping method according to the first or second aspect, further comprising:

allowing a second laser light beam serving as exciting light, with a wavelength corresponding to an light absorption exerted therein and being larger than the wavelength of the first laser light beam, to be made incident into a second region deeper than the first region for forming the plasma doping layer on a substrate surface side, in a direction orthogonal to the surface of the substrate during the plasma discharging process;

receiving second scattered light from the substrate at a detector;

spectrum-resolving the second scattered light received by the detector, by a spectroscope,

computing the second scattered light at the operation unit based on a spectrum with unnecessary exciting wavelengths having been removed by spectrum division at the spectroscope, and computing a film property or film thickness of an amorphous layer near the surface of the substrate at the operation unit based on a difference between the computed second scattered light and the first scattered light; and

while controlling plasma processing conditions at the control device so as to allow the computed film property or film thickness of the amorphous layer to be equal to a set film property or film thickness of the amorphous layer, injecting the dopant into the surface of the substrate to form the plasma doping layer.

According to a fourth aspect of the present invention, there is provided the plasma doping method according to the third aspect, wherein the second laser light beam is used as reference light with a wavelength corresponding to an light absorption exerted in the second region having a depth exceeding 100 nm below the plasma doping layer on the surface of the substrate, with the wavelength of the second laser light beam to be used being set to 420 nm to 1100 nm.

According to a fifth aspect of the present invention, there is provided the plasma doping method according to the third or fourth aspect, wherein a wavelength having an absorption coefficient of 1/100 or less relative to an absorption coefficient of the first laser light beam is used as the wavelength of the second laser light beam.

According to a sixth aspect of the present invention, there is provided the plasma doping method according to any one of the first to fifth aspects, wherein the laser light beam is applied onto a detection pattern within a scribe line of the substrate.

According to a seventh aspect of the present invention, there is provided a plasma doping apparatus comprising:

a vacuum chamber;

an electrode placed in the vacuum chamber to allow a substrate to be mounted thereon;

a dopant gas supply device for supplying a dopant gas into the vacuum chamber;

a pressure control device for maintaining an inside of the vacuum chamber at a certain fixed pressure;

a plasma generating device for generating a plasma in the vacuum chamber;

a high-frequency power applying device for applying a high-frequency power to the substrate;

a first laser light beam outputting device for allowing, during a plasma discharging process, a first laser light beam serving as exciting light with a wavelength corresponding to an light absorption exerted therein, to be made incident into a first region for forming the plasma doping layer on a substrate surface side in a direction orthogonal to the surface of the substrate;

a detector for receiving first scattered light scattered from the substrate in a direction orthogonal to the surface of the substrate;

a spectroscope for spectrum-resolving the first scattered light received by the detector;

an operation unit for computing the first scattered light based on a spectrum with unnecessary exciting wavelengths having been removed by spectrum division at the spectroscope, as well as for computing an impurity density of the plasma doping layer on the surface of the substrate based on the computed first scattered light; and

a control device for feed-back controlling plasma processing conditions so as to allow the impurity density computed at the operation unit to be equal to a set impurity density.

According to an eighth aspect of the present invention, there is provided the plasma doping apparatus according to the seventh aspect, wherein a wavelength of an exciting laser light beam having an absorption coefficient corresponding to a thickness of 5 nm to 100 nm of the plasma doping layer to be formed in the substrate is used as the wavelength of the first laser light beam, with the wavelength of the first laser light beam to be used being set to 190 nm to 420 nm.

According to a ninth aspect of the present invention, there is provided the plasma doping apparatus according to the seventh or eighth aspect, further comprising:

a second laser light beam outputting device for allowing, a second laser light beam serving as exciting light with a wavelength corresponding to an light absorption exerted therein and being larger than the wavelength of the first laser light beam, to be made incident into a second region deeper than the first region for forming the plasma doping layer on a substrate surface side in a direction orthogonal to the surface of the substrate during the plasma discharging process, wherein

the detector receives second scattered light from the substrate,

the spectroscope spectrum-resolves the second scattered light received by the detector,

the operation unit computes the second scattered light based on a spectrum with unnecessary exciting wavelengths having been removed by spectrum division at the spectroscope, as well as computes a film property or film thickness of an amorphous layer near the surface of the substrate based on a difference between the computed second scattered light and the first scattered light, and

the control device controls plasma processing conditions so as to allow the computed film property or film thickness of the amorphous layer to be equal to a set film property or film thickness of the amorphous layer.

According to a 10th aspect of the present invention, there is provided the plasma doping apparatus according to the ninth aspect, wherein the second laser light beam is used as reference light with a wavelength corresponding to an light absorption exerted in the second region at a depth exceeding 100 nm below the plasma doping layer on the surface of the substrate, with the wavelength of the second laser light beam being set to 420 nm to 1100 nm.

According to an 11th aspect of the present invention, there is provided the plasma doping apparatus according to the ninth or 10th aspect, wherein the wavelength of the second laser light beam has an absorption coefficient of 1/100 or less relative to an absorption coefficient of the first laser light beam.

### EFFECTS OF THE INVENTION

By directly monitoring a portion really close to the surface of the substrate, the density of the impurity at the depth of 10 nm to 100 nm from the surface of the substrate can be more accurately measured in real time during the plasma doping process. Accordingly, based on the measurement results, the plasma doping processing conditions, such as a high-frequency power to be applied from the plasma generating high-frequency power supply, plasma doping processing time, a flow rate of a gas into the vacuum chamber, or a pressure in the vacuum chamber, can be accurately feed-back controlled by the control device. Therefore, the impurity density is correctly controlled so that a desired impurity density can be accurately obtained.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a constructional view of a plasma doping apparatus according to first and second embodiments of the present invention;

FIG. 2 is a constructional view of a laser oscillator and a laser receiving device according to the first embodiment of the present invention;

FIG. 3 is a graph indicating a Raman scattering spectrum (with a peak of silicon in the vicinity of 521 cm⁻¹ and a peak of amorphous in the vicinity of 470 cm⁻¹) obtained during a plasma discharging operation in a helium gas in a plasma doping process according to the first embodiment of the present invention;

FIG. 4 is a graph indicating a Raman scattering spectrum (with a peak of doping (impurity) in the vicinity of 105 cm⁻¹) obtained during the plasma discharging operation in the helium gas with diborane supplied thereto in the plasma doping process according to the first embodiment of the present invention;

FIG. 5 is an explanatory view for explaining a surface state of a process substrate during the plasma doping process according to the first embodiment of the present invention;

FIG. 6 is a graph indicating a dependence on plasma doping processing time of a sheet resistance in the plasma doping process according to the first embodiment of the present invention;

FIG. 7 is a graph indicating a wave-length dependence of a light absorption coefficient of silicon;

FIG. 8 is a graph indicating a processing-time dependence of the size of each of peaks of an impurity signal and an amorphous signal;

FIG. 9 is a detailed view of a laser irradiated portion on a process substrate;

FIG. 10 is an explanatory view for explaining an invasion in a depth direction of each of a short-wavelength laser and a long-wavelength laser in the vicinity of the surface of a process substrate according to the second embodiment of the present invention;

FIG. 11A is a flow chart for detecting a density of an impurity on the process substrate in the plasma doping process according to the first embodiment of the present invention;

FIG. 11B is a flow chart for detecting an amorphous depth of the process substrate in the plasma doping process according to the second embodiment of the present invention;

FIG. 12 is a constructional view of a laser oscillator and a laser receiving device according to the second embodiment of the present invention; and

FIG. 13 is a constructional view of a conventional plasma doping apparatus.

### DETAILED DESCRIPTION OF THE PREFERRED EMBODIMENTS

Before the description of the present invention proceeds, it is to be noted that like parts are designated by like reference numerals throughout the accompanying drawings.

Referring to the drawings, the following description will discuss in detail embodiments of the present invention.

### First Embodiment

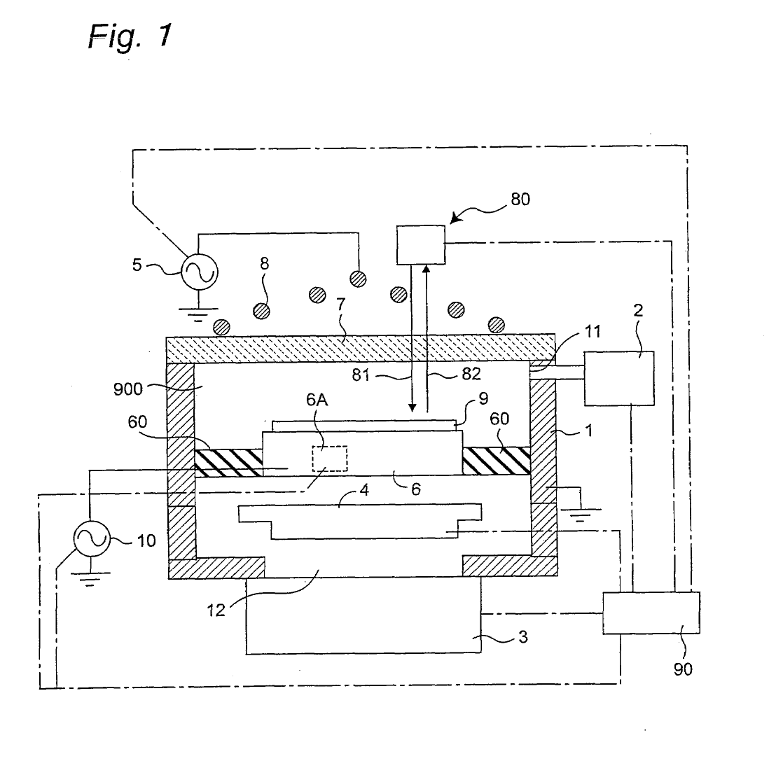

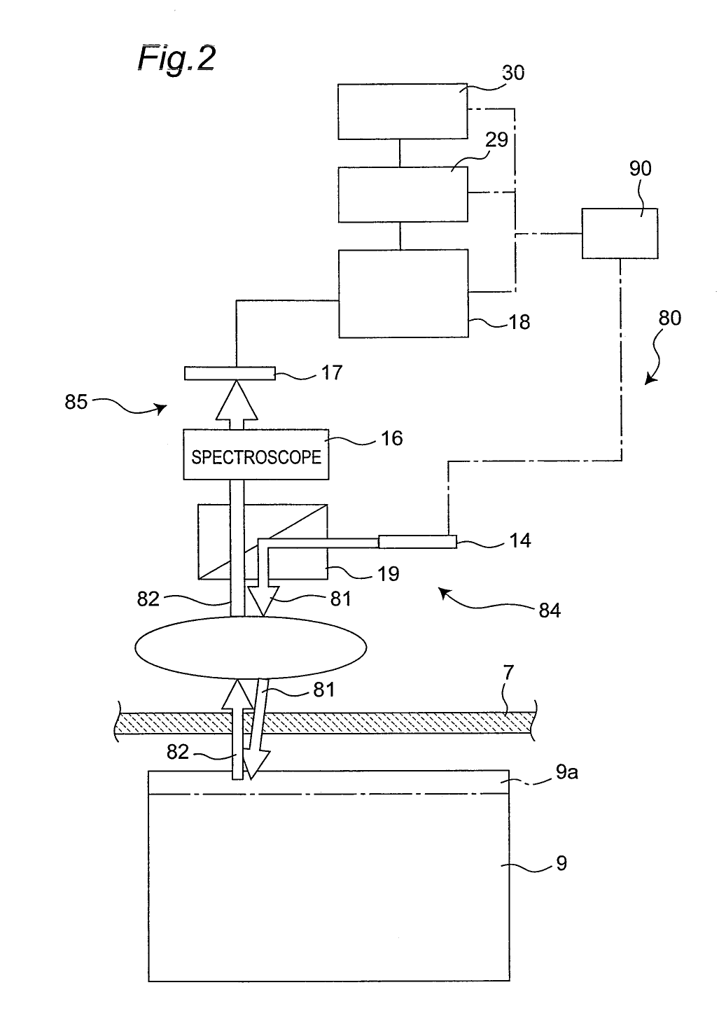

Referring to FIGS. 1 and 2, the following description will discuss a plasma doping method and a plasma doping apparatus in accordance with the first embodiment of the present invention.

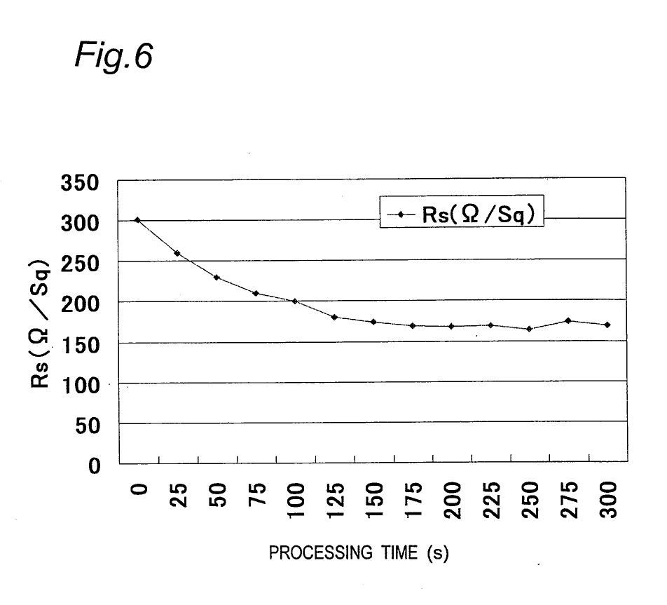

FIG. 1 shows a cross-sectional view and a plan view of the plasma doping apparatus to be used in the first embodiment of the present invention. In FIG. 1, while supplying a predetermined gas into a vacuum container 1 that is earthed and has a vacuum chamber 900 formed therein, through a gas supply inlet 11 on a side wall of the vacuum container 1 from a gas supply device 2 serving as one example of a dopant gas supply device, an evacuation process of the vacuum container 1 is carried out through an exhaust outlet 12 formed on a bottom face of the vacuum container 1 using a turbo molecular pump 3 serving as one example of an exhausting device, so that the inside of the vacuum container 1 is maintained at a predetermined pressure using a pressure-adjusting valve 4 for opening and closing the exhaust outlet 12. These turbo molecular pump 3, the pressure-adjusting valve 4, and a pressure-controlling unit of a control device 90 to be described later are allowed to form a pressure control device. By supplying a high-frequency power of, for example, 13.56 MHz using a plasma generating high-frequency power supply 5 to a coil 8 placed in the vicinity of an upper face outside a dielectric window 7 formed on an upper portion of the vacuum container 1 so as to face a sample electrode 6, an inductive coupling type plasma can be generated in a space above the sample electrode 6 of the vacuum container 1 inside the vacuum container 1 as well as on the periphery thereof. These plasma generating high-frequency power supply 5 and the coil 8 are allowed to form a plasma generating device. A substrate (process substrate) serving as one example of a sample such as a silicon substrate 9 is placed on the sample electrode 6 placed in the vacuum container 1 with an insulator 60 interposed therebetween. According to processing time of the plasma doping process, a desired dose quantity (sheet resistance Rs) can be obtained. FIG. 6 shows relationship of the quantity of dose (sheet resistance Rs) to the processing time. Accordingly, the processing time of the plasma doping process required for obtaining a desired quantity of dose is obtained from the graph of FIG. 6.

A high-frequency power applying high-frequency power supply 10 serving as one example of a high-frequency power applying device used for supplying a high-frequency power is connected to the sample electrode 6. The high-frequency power applying high-frequency power supply 10 is driven and controlled by the control device 90 so as to allow the process substrate 9 serving as one example of the sample to be placed on the sample electrode 6 to have a negative electric potential relative to the plasma. Accordingly, the electric potential of the sample electrode 6 can be controlled.

The control device 90 is formed to control respective operations of the gas-supply device 2, the turbo molecular pump 3, the pressure-adjusting valve 4, the high-frequency power supply 5, the high-frequency power supply 10, a temperature adjusting device 6A to be described later, and a monitoring device 80 so that a plasma doping method can be carried out. In the monitoring device 80, a signal amplifying device 18, an operation unit 29, a comparison determining unit 30, laser oscillators 14, 14A, and 14B, which are to be described later, and the control device 90 are connected to each other so as to control the respective operations.

After placing the process substrate 9 on the sample electrode 6, with the temperature of the sample electrode 6 being maintained, for example, at 10° C. using the temperature adjusting device 6A built in the sample electrode 6, the vacuum container 1 is evacuated through the exhaust outlet 12 using the turbo molecular pump 3, with, for example, 50 sccm of a helium gas being supplied into the vacuum container 1 from the gas-supply device 2 through the gas-supply inlet 11 and 3 sccm of a diborane (B₂H₆) gas serving as one example of a doping material gas (dopant gas) being supplied thereinto, and the pressure-adjusting valve 4 is controlled by the control unit 90 so that the pressure of the vacuum container 1 is maintained, for example, at 3 Pa. The diborane gas is used as one example of the doping material gas to be used in a silicon semiconductor. Alternatively used is an n-type semiconductor doping material gas such as arsine, phosphine, arsenic trifluoride, arsenic pentafluoride, arsenic trichloride, arsenic pentachloride, phosphorus trichloride, phosphorus pentachloride, phosphorus trifluoride, phosphorus pentafluoride, or phosphorus oxychloride, or a p-type semiconductor doping material gas such as diborane, boron trichloride, boron trifluoride, or boron tribromide.

The following description will discuss the monitoring device 80 for monitoring an impurity density in the vicinity of the surface of the process substrate 9.

FIG. 2 is a schematic view of the monitoring device 80. The monitoring device 80 is configured by an optical system 84 for applying a laser light beam 81 to the process substrate 9 in a direction orthogonal to the surface of the process substrate 9, a detection optical system 85 for detecting scattered light (radiated light emitted from the process substrate 9 in a direction orthogonal to the surface of the process substrate 9) 82 from the process substrate 9, a signal amplification device 18 for amplifying the light detected by the detection optical system 85, and the operation unit 29 for computing a detection spectrum using the laser light beam detected by the detection optical system 85 and amplified by the signal amplification device 18. In FIG. 2, in a case where the laser light beam 81 is illustrated so as to be applied in a direction orthogonal to the surface of the process substrate 9, the laser light beam 81 and the scattered light 82 are overlapped with each other to cause difficulty in viewing. Thus, the laser light beam 81 and the scattered light 82 are illustrated so as to be tilted relative to the surface of the process substrate 9 for a better view. However, actually, the laser light beam 81 is applied to the process substrate 9 in the direction orthogonal to the surface thereof, and the scattered light 82 is emitted in the direction orthogonal to the surface of the process substrate 9. In the drawings hereinafter, illustrations thereof are given in the same manner.

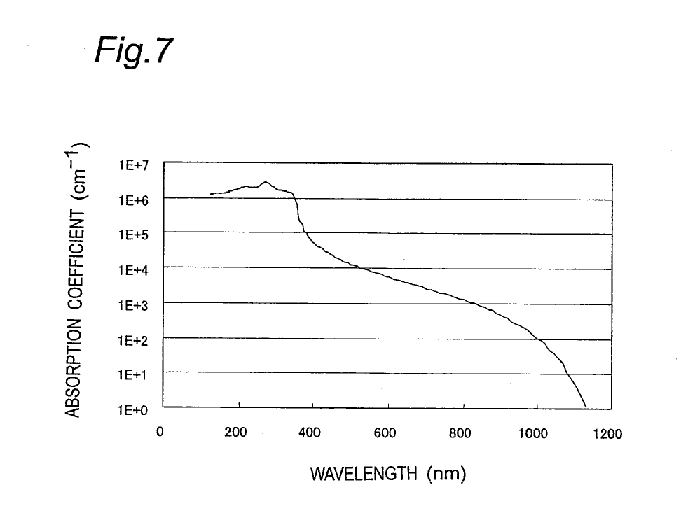

The optical system 84 for applying the laser light beam 81 to the process substrate 9 is configured by the laser oscillator 14 for emitting the laser light beam 81, a wavelength separating plate 19 for separating the wavelength of the laser light beam 81 emitted from the laser oscillator 14, and a condensing lens 15 for condensing the laser light beam 81 emitted from the laser oscillator 14 and transmitted through the wavelength separating plate 19 onto the process substrate 9. The laser light beam 81 emitted from the optical system 84 is allowed to pass through the dielectric window 7 having a high transmittance with respect to a predetermined wavelength. The laser oscillator 14, the wavelength separating plate 19, and the condensing lens 15 are allowed to form one example of a laser light emitting device. The laser oscillator 14, the condensing lens 15, and the wavelength separating plate 19 are installed outside the dielectric window 7 provided on the upper portion of the vacuum container 1 so that the laser light beam 81 is applied to the process substrate 9 in the vacuum container 1 through the condensing lens 15, the wavelength separating plate 19, and the dielectric window 7. The range (size) of a measuring region 9a on the surface of the process substrate 9 can be arbitrarily changed by altering an NA (numerical aperture) of the condensing lens 15, while the range being limited within an impurity layer (plasma doping layer). The plasma doping layer is prepared to have a depth about 100 nm at the most from the surface of the process substrate 9. As one example, with respect to the laser wavelength of the laser light beam 81, in a case where the process substrate 9 is made of silicon, an ultraviolet laser that can emit the laser light beam 81 having a laser wavelength allowing the silicon to have an absorption coefficient corresponding to 5 to 100 nm is preferably used as the laser oscillator 14. Since the laser wavelength within the above range (5 to 100 nm) of the laser light 81 is absorbed by the measuring region 9a of the process substrate 9, the laser light beam 81 is hardly allowed to reach a region having a depth larger than 100 nm from the surface of the process substrate 9. The laser light beam 81 absorbed by the measuring region 9a of the process substrate 9 having a depth in the range of from 5 to 100 nm from the surface of the process substrate 9 serves as exciting light, a part of which is emitted from the surface of the process substrate 9 as Raman scattered light 82. As one actual example, in a case where the process substrate 9 is made of silicon with the depth of the impurity being set to 20 nm, an absorbing depth from the surface of the process substrate 9 is set to 20 nm. The Raman scattered light is described as follows: Upon applying light having a certain wavelength to a substance, light having the same wavelength is scattered (Rayleigh-scattered), and a part of the scattered light is scattered with its wavelength varied in accordance with oscillation of molecules forming the substance. Such a phenomenon is referred to as “Raman scattering”, and such light scattered with the varied wavelength is referred to as “Raman scattered light”. The absorbing depth from the surface of the process substrate 9 is provided as the inverse of the light absorption coefficient of a certain wavelength of the laser light 81. FIG. 7 is a graph indicating the relationship between the light absorption coefficient of silicon and the wavelength, and represents the wavelength dependence of the light absorption coefficient of silicon. Based on the relationship between the light absorption coefficient of silicon and the wavelength indicated in FIG. 7, as one example, in a case where the measuring region 9a of the process substrate 9 is set to have an absorbing depth of 20 nm from the surface of the process substrate 9, the laser light beam 81 having a light emission wavelength of 352 nm or less corresponding to the absorbing depth of 20 nm is preferably selected. As one example, the laser wavelength is set to 248 nm, which is assumed as the wavelength same to that of an excimer laser beam, so that the excimer laser can be used (see FIG. 7). Specifically, for example, in a case where the plasma doping depth is defined to correspond to a depth in which a density of 1e18 cm⁻³ is attained, the laser light 81 having a wavelength with an absorption coefficient approximately equivalent to a desired depth is preferably used. Since the absorption depth corresponds to the inverse of the light absorption coefficient of a certain wavelength as described earlier, it is preferable to select the laser light beam 81 with a light emission wavelength having a light absorption coefficient equivalent to the depth of an impurity layer (plasma doping layer) to be formed in the plasma doping method (in other words, a light absorption coefficient the inverse of which corresponds to the depth of the impurity layer (plasma doping layer)) or less.

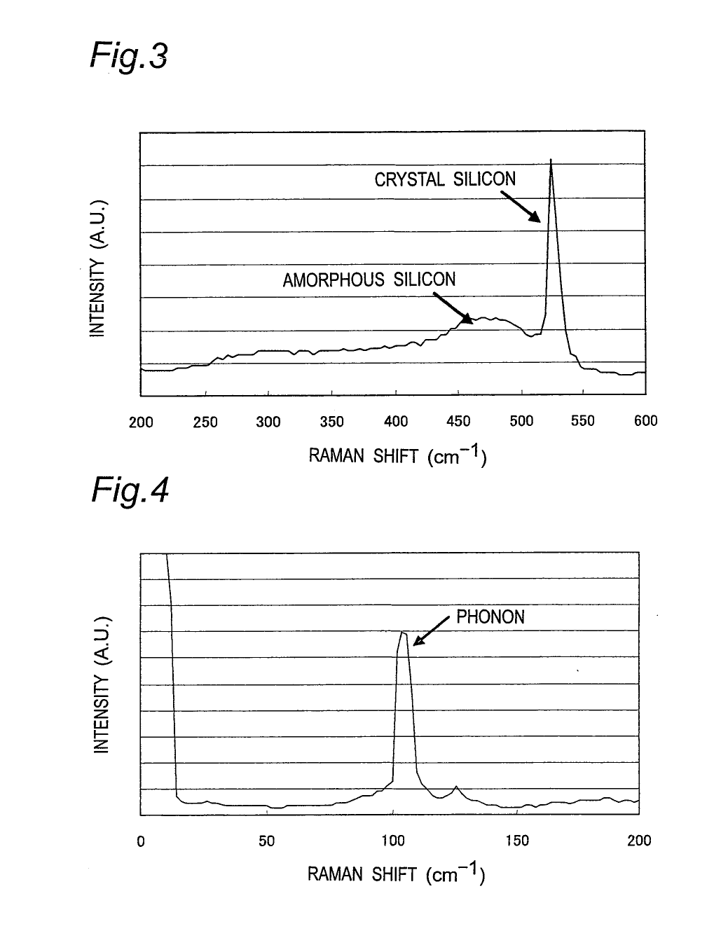

The detection optical system 85 for detecting the scattered light 82 from the process substrate 9 is configured by a spectroscope 16 that has a prism or a diffraction grating and a detector 17 for detecting scattered light for every wavelength. The scattered light 82 from the process substrate 9 enters the detection optical system 85 after passing through the dielectric window 7 formed on the upper portion of the vacuum container 1. The scattered light 82 emitted from the measuring region 9a of the process substrate 9 irradiated with the laser light beam 81 is allowed to pass through the dielectric window 7, is transmitted through the condensing lens 15 and the wavelength separating plate 19, and is spectrum-resolved by the prism or the diffraction grating of the spectroscope 16, so as to be wavelength-separated. The light wavelength-separated by the spectroscope 16 is detected by the detector 17 for every wavelength, the light detected by the detector 17 is amplified by the signal amplifier 18, and unnecessary spectra of the detected and amplified laser light are removed by computing processes in the operation unit 29, so that a light emission spectrum (in other words, detection spectrum) of the scattered light 82 as shown in FIGS. 3 and 4 can be obtained as a spectrum required for controlling the impurity density.

Since the depth of the impurity formed in the process substrate 9 in the plasma doping method is set to several nms to 250 nm, a light emission wavelength of 150 to 420 nm corresponding to the absorbing depth may be selected as the laser light emission wavelength of the laser light 81. Moreover, by taking out signals having only the frequency components so as to form the laser light emission wavelength into pulses, a laser light emitting device as another example different from the laser oscillator 14 may be provided. In this structure, it is possible to remove influences of noise components and plasma discharging. In this case, as the pulse generation method, an input current to the laser oscillator 14 can be generated as pulses. A light-shielding plate for regularly shielding light may be used in the pulse generating method. It is required to use the pulse frequency of other than the laser light emission wavelength of the laser light 81, the frequency of the plasma generating high-frequency power supply 5, the power frequency supplied in an area in which the plasma doping apparatus is used (60 Hz in the western area of Japan and in the United States), and transmission frequencies for use in apparatuses used in the plasma doping apparatus. In a case where a signal component is sufficiently large, it is not necessary to generate the above-mentioned pulse.

FIG. 3 is a graph indicating an example of a spectrum of Raman scattering measured during the plasma discharging process using a helium gas. In the graph of FIG. 3, the axis of ordinates represents the intensity and the axis of abscissas represents the Raman shift. As shown in FIG. 3, it is found that, as time elapses, what appear are a peak (peak of crystallized silicon) 521 cm⁻¹ derived only from the single crystal silicon and a peak 470 cm⁻¹ derived from amorphous silicon.

Moreover, in a case where diborane is supplied in the vacuum container 1, as shown in FIG. 4, it is found that what appears is a peak 105 cm⁻¹ (peak of an impurity as phonon) derived from a wavelength different from the above-mentioned spectrum. Also in FIG. 4, the axis of abscissas represents the intensity and the axis of ordinates represents the Raman shift.

Accordingly, it is found that the crystal state of silicon can be detected at the peak of 521 cm⁻¹ and at the peak of 470 cm⁻¹, respectively, and the state of the impurity can be detected at the peak near 105 cm⁻¹.

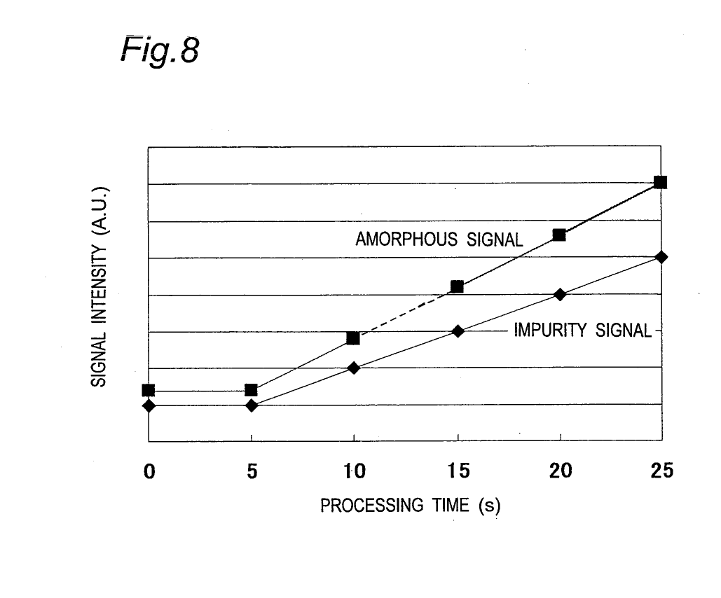

As the plasma doping process proceeds, the impurity is injected into the process substrate 9, so that the Raman intensity (see the axis of ordinates) of the impurity signal indicating the density of impurity gradually increases relative to the processing time (see the axis of abscissas), as shown in FIG. 8.

Since the object in the first embodiment is to control the density of the impurity, the peak of 521 cm⁻¹ and the peak of 470 cm⁻¹ indicating the crystal states of silicon are removed upon computing in the operation unit 29 as unnecessary spectra, and only the peak near 105 cm⁻¹ indicating the density state of the impurity is extracted. Further, by taking into consideration the extracted peak and the processing-time dependence on the size of the peak of the impurity signal shown in FIG. 8, the processing of the plasma doping process can be controlled by the control device 90. More specifically, by taking into consideration the extracted peak and the processing-time dependence on the size of the peak of the impurity signal, the control device 90 is allowed to feed-back control plasma doping processing conditions, such as the high-frequency power to be applied by the plasma generating high-frequency power supply 5, the plasma doping processing time, the flow rate of the gas into the vacuum container 1, or the pressure in the vacuum container 1, so that a desired (set) impurity density can be obtained accurately. In this case, as one example of the feed-back control, in a case where the intensity of the extracted peak is smaller than the predetermined intensity, the difference is calculated by the operation unit 29, so that the plasma doping processing time corresponding to the intensity of the calculated difference is calculated by the operation unit 29 in accordance with the relationship between the extracted peak and the processing-time dependence on the size of the peak of the impurity signal. Thus, the doping processing time can be prolonged by the calculated plasma doping processing time. In a case where the plasma doping processing conditions are controlled during feed-back control, the plasma doping processing time can be controlled most easily.

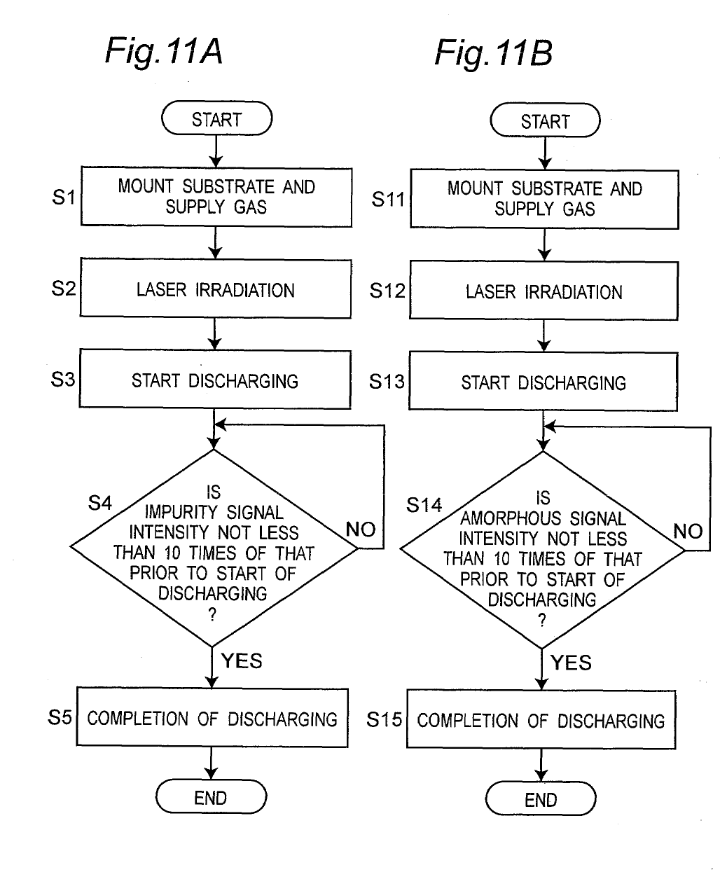

Referring to a flow chart in FIG. 11A, the following description will discuss the plasma doping method using the plasma doping apparatus according to the first embodiment. The following operations can be basically carried out under control of the control device 90.

First in step S1, after the process substrate 9 has been mounted on the sample electrode 6, under control of the control device 90, with a predetermined gas being supplied into the vacuum container 1 from the gas supply device 2 through the gas supply inlet 11 on the side wall of the vacuum container 1, an evacuation process in the vacuum container 1 is carried out through the exhaust outlet 12 on the bottom face of the vacuum container 1 using a turbo molecular pump 3, so that the inside of the vacuum container 1 is maintained at a predetermined pressure using the pressure-adjusting valve 4 for opening and closing the exhaust outlet 12.

Then in step S2, under control of the control device 90, the laser light beam 81 emitted from the laser oscillator 14 is refracted downward by the wavelength separating plate 19, and is allowed to pass through the dielectric window 7, while being condensed by the condensing lens 15, so as to irradiate the process substrate 9 in the vacuum container 1. The scattered light 82 released from the measuring region 9a of the process substrate 9 irradiated with the laser light beam 81 is allowed to pass through the dielectric window 7, is transmitted through the condensing lens 15 and the wavelength separating plate 19, and is wavelength-separated by the prism or the diffraction grating of the spectroscope 16. The light, wavelength-separated by the spectroscope 16, is detected by the detector 17 for every wavelength, and based upon the detection results, unnecessary spectra of the scattered light 82 are removed by the operation unit 29, so that a Raman intensity indicating the intensity of the impurity signal is obtained by the operation unit 29. The intensity of the impurity signal obtained by the operation unit 29 is temporarily stored in the comparison determination unit 30 as the intensity of the impurity signal prior to the start of discharging.

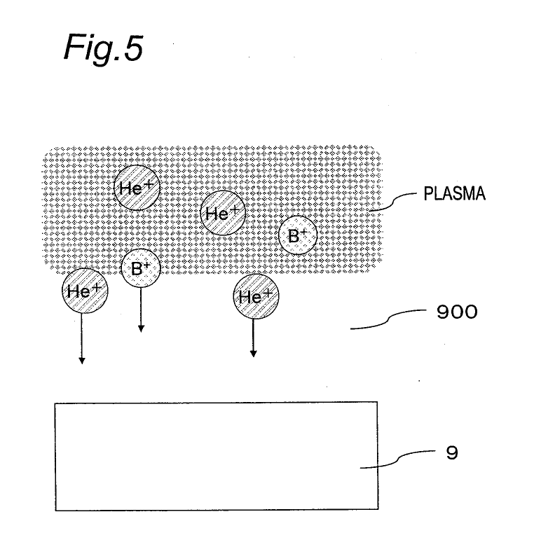

In step S3, under control of the control device 90, a high-frequency power of 13.56 MHz, as one example, is supplied to the coil 8 from the plasma generating high-frequency power supply 5, so that an inductive coupling type plasma is generated in a space above the sample electrode 6 of the vacuum container 1 inside the vacuum container 1 as well as on the periphery thereof. In this case, the high-frequency power applying high-frequency power supply 10 is driven and controlled by the control device 90, and the electric potential of the sample electrode 6 is controlled, so that the process substrate 9 is allowed to have a negative electric potential with respect to the plasma. Thus, the plasma doping process is started. That is, as shown in FIG. 5, boron ions in the plasma are introduced into the surface of the sample 9 using the high-frequency power supply 10.

In step S4, the scattered light 82 released from the measuring region 9a of the process substrate 9 irradiated with the laser light beam 81 is allowed to pass through the dielectric window 7, is transmitted through the condensing lens 15 and the wavelength separating plate 19, and is wavelength-separated by the prism or the diffraction grating of the spectroscope 16. The light, wavelength-separated by the spectroscope 16, is detected by the detector 17 for every wavelength, and based upon the detection results, unnecessary spectra of the scattered light 82 are removed by the operation unit 29, so that a Raman intensity indicating the intensity of the impurity signal is obtained by the operation unit 29. It is determined by the comparison determination unit 30 whether or not the intensity of the impurity signal obtained by the operation unit 29 is not less than ten times higher than the intensity of the impurity signal prior to the start of discharging as being temporarily stored in step S2. It is defined that the comparison determination unit 30 determines whether or not the intensity of the impurity signal is not less than ten times higher than the intensity of the impurity signal prior to the start of discharging. However, this is just one example, and the state where the intensity becomes ten times higher corresponds to a state where the quantity of dose reaches about 10¹⁵. The doping process is continuously carried out without proceeding to the next step until the intensity of the impurity signal obtained in step S4 becomes not less than ten times higher than the intensity of the impurity signal prior to the start of discharging as being temporarily stored in step S2. In this case, by taking into consideration the intensity of the impurity signal (the extracted peak) obtained by the operation unit 29 and the processing-time dependence (see FIG. 8) on the size of the peak of the impurity signal, the control device 90 is allowed to feed-back control the plasma doping processing conditions such as the high-frequency power to be applied by the plasma generating high-frequency power supply 5, the plasma doping processing time, the flow rate of the gas into the vacuum container 1, the pressure in the vacuum container 1, or the like.

When the intensity of the impurity signal obtained in step S4 becomes not less than ten times higher than the intensity of the impurity signal prior to the start of discharging as being temporarily stored in step S2, the process proceeds to next step S5 since a desired (set) impurity density is obtained.

In step S5, under control of the control device 90, the plasma generating high-frequency power supply 5 and the high-frequency power applying high-frequency power supply 10 are turned off to complete the plasma discharging, thereby completing the plasma doping process.

In accordance with the first embodiment, by directly monitoring the outermost portion of the surface of the process substrate 9, the impurity density at the depth of 5 nm to 100 nm from the surface of the process substrate 9 can be more accurately measured in real time during the plasma doping process. Thus, based upon the measurement results, the plasma doping processing conditions such as the high-frequency power to be applied by the plasma generating high-frequency power supply 5, the plasma doping processing time, the flow rate of the gas into the vacuum container 1, the pressure inside the vacuum container 1, or the like can be accurately feed-back controlled by the control device 90. Therefore, the impurity density is correctly controlled so that a desired (set) impurity density can be accurately obtained. Since the outermost portion of the surface of the process substrate 9 is directly monitored, the amount of the impurity discharged from the wall of the vacuum container 1 can also be taken into consideration, enabling more accurate control.

### Second Embodiment

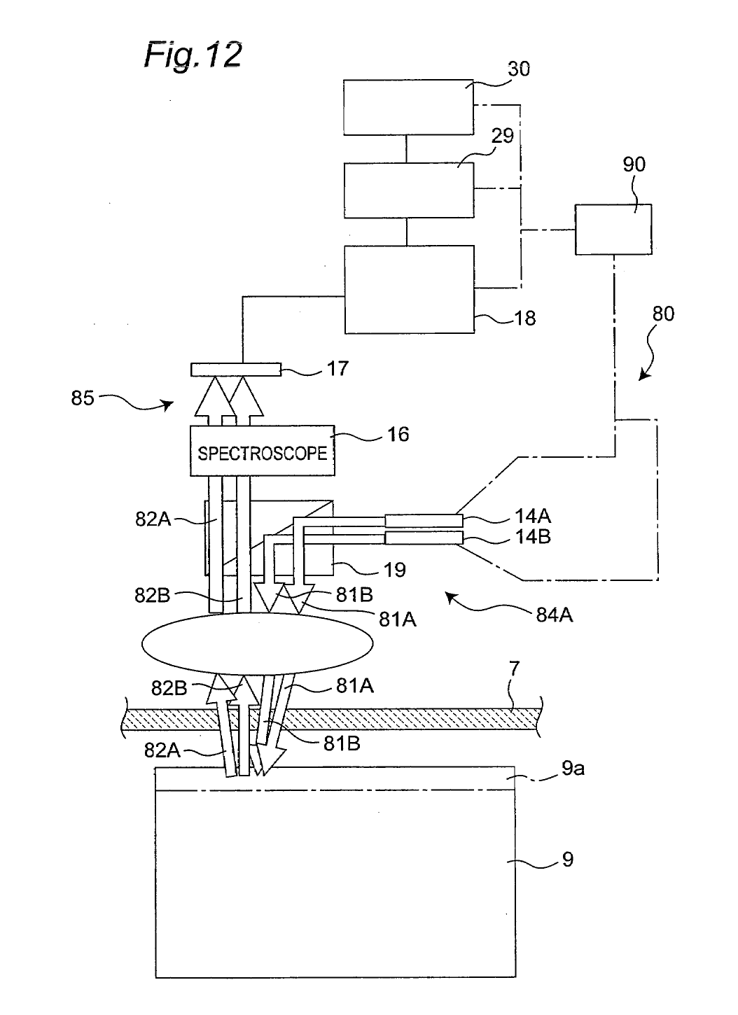

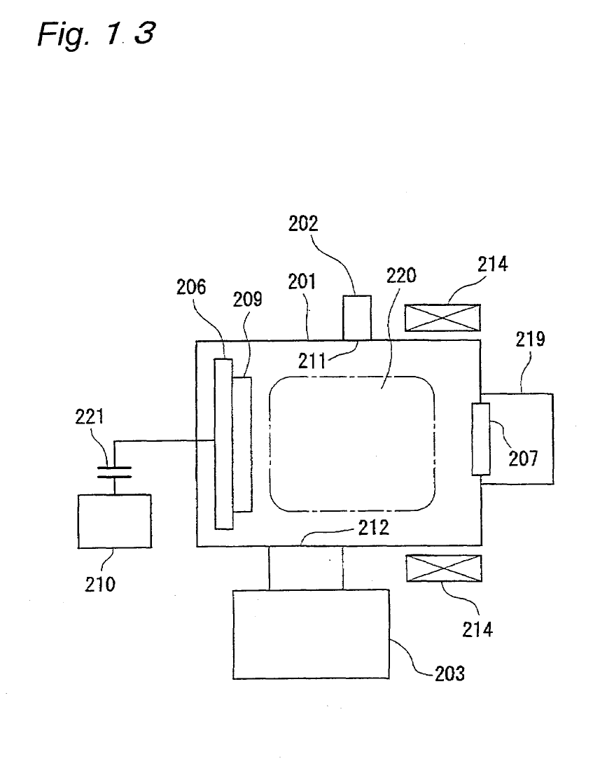

Referring to FIGS. 1 and 12, the following description will discuss the second embodiment of the present invention.

Since the basic structure of a plasma doping apparatus to be used in the second embodiment is similar to that of the plasma doping apparatus used in the first embodiment of FIG. 1, description will be given mainly on different points thereof. The largest difference is that two laser oscillators 14A and 14B for emitting laser light beams 81A and 81B having wavelengths different from each other (that is, long-wavelength laser light beam 81A and short-wavelength laser light beam 81B) are installed, so that detection similar to that of the first embodiment is carried out by the short-wavelength laser light beam 81B, while scattered light 82B with a short wavelength (radiated light with a short wavelength emitted from the process substrate 9 in the direction orthogonal to the surface of the process substrate 9) emitted from a shallow region is (measuring region) 9a from the surface of the process substrate 9 contains information on the crystal state of the surface of the process substrate 9, the information being buried in other information, so that, using, as a reference signal, scattered light 82A with a long wavelength (radiated light with a long wavelength emitted from the process substrate 9 in the direction orthogonal to the surface of the process substrate 9) from a deep region 9g from the surface of the process substrate 9, the difference between the scattered light 82B having a short wavelength from the shallow region (measuring region) 9a and the scattered light 82A having a long wavelength from the deep region 9g is computed to take out information on the crystal state (amorphous state) of the surface of the process substrate 9. Therefore, in addition to the impurity density in the measuring region 9a of the process substrate 9, the crystal state can be detected. Similarly to the first embodiment, the plasma doping layer is prepared to have the depth of about 100 nm at the most from the surface of the process substrate 9.

While the monitoring device 80 is used for monitoring the impurity density in the vicinity of the surface of the process substrate 9 in the first embodiment, the monitoring device 80 is used for monitoring the impurity density and the crystal state in the second embodiment.

The monitoring device 80 is configured by an optical system 84A, a detection optical system 85, a signal amplifying device 18, and an operation unit 29, and only the optical system 84A is greatly different in structure.

More specifically, as shown in FIG. 12, the optical system 84A is used for applying laser light beams 81A and 81B having two kinds of wavelengths (laser light beam 81A having a long emission wavelength and laser light beam 81B having a short emission wavelength), and is configured by the laser oscillators 14A and 14B serving as one example of laser light emitting devices that respectively emit the laser light beams 81A and 81B having two kinds of wavelengths, the condensing lens 15, and the wavelength separating plate 19. The laser light beams 81A and 81B emitted from the optical system 84A respectively pass through the dielectric window 7 having a high transmittance relative to the respective predetermined wavelengths. The laser oscillators 14A and 14B, the condensing lens 15, and the wavelength separating plate 19 are provided outside the dielectric window 7 placed on the upper portion of the vacuum container 1, and the laser light beams 81A and 81B are respectively applied to the process substrate 9 in the vacuum container 1 in the direction orthogonal to the surface of the process substrate 9 through the wavelength separating plate 19, the condensing lens 15, and the dielectric window 7. The range (size) of the measuring region 9a on the surface of the process substrate 9 can be arbitrarily changed by altering the NA (numerical aperture) of the condensing lens 15.

As to be described below, the short emission wavelength of the laser light beam 81B is set similarly to that of the laser light beam 81 of the first embodiment.

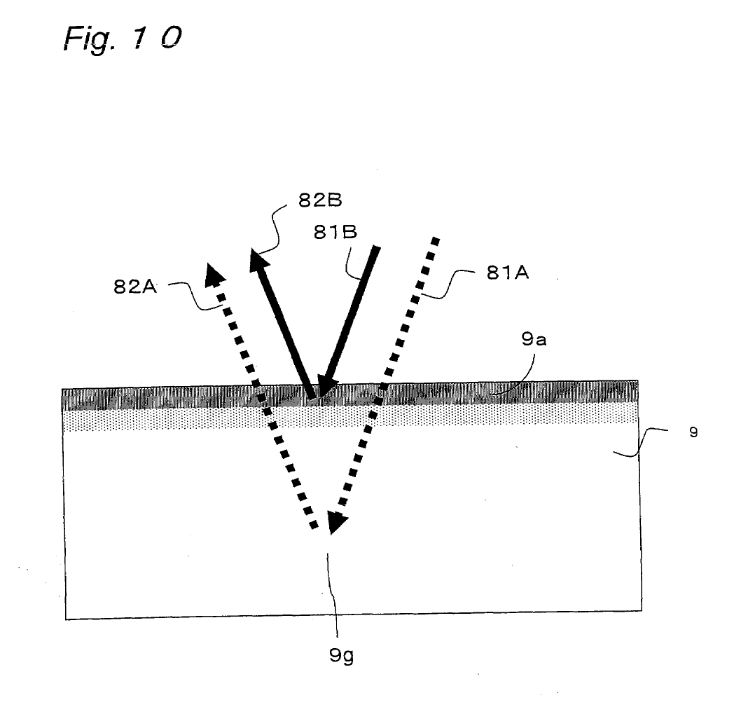

As one example, in the short emission wavelength of the laser light beam 81B, when the process substrate 9 is made of, for example, silicon, an ultraviolet laser capable of emitting the laser light beam 81B having a laser wavelength allowing the silicon to have an absorption coefficient of 5 to 100 nm is preferably used as the laser oscillator 14B. Since the laser wavelengths in the above-mentioned range (5 to 100 nm) of the laser light beam 81B having the short emission wavelength are absorbed by the measuring region 9a of the process substrate 9, the laser light beam 81B is hardly allowed to reach the region 9g (see FIG. 10) having a depth larger than 100 nm from the surface of the process substrate 9. The laser light beam 81B absorbed in the measuring region 9a of the process substrate 9 having the depth of 5 to 100 nm from the surface of the process substrate 9 serves as exciting light, part of which is emitted from the surface of the process substrate 9 as Raman scattered light 82B. As one actual example, in a case where the process substrate 9 is made of silicon with the depth of the impurity being set to 20 nm, the absorbing depth from the surface of the process substrate 9 is set to 20 nm.

As described in the first embodiment, regarding the laser light beam 81B having a short wavelength, as shown in FIG. 3, the crystal states of silicon are respectively detected at a peak of 521 cm⁻¹ and at a peak of 470 cm⁻¹, while the state of the impurity can be detected at a peak in the vicinity of 105 cm⁻¹.

As the plasma doping process proceeds, the impurity is injected into the process substrate 9, so that as shown in FIG. 8, the Raman intensity (see the axis of ordinates) of the amorphous signal indicating the crystal state gradually increases as the processing time elapses (see the axis of abscissas), while the Raman intensity (see the axis of ordinates) of the impurity signal indicating the density of the impurity also gradually increases as the processing time elapses (see the axis of abscissas).

Since the object of the second embodiment is to control the density of the impurity and the crystal state of the silicon, upon controlling the density of the impurity, the same processes as those of the first embodiment are carried out, while, upon controlling the crystal state of the silicon, the peak in the vicinity of 105 cm⁻¹ indicating the state of the impurity is removed as an unnecessary spectrum upon computing in the operation unit 29. Only the peak of 521 cm⁻¹ and the peak of 470 cm⁻¹ indicating the crystal states of silicon are extracted, and taking into consideration the extracted peaks and the processing-time dependence on the size of the peak of the amorphous signal shown in FIG. 8, the plasma doping process can be controlled by the control device 90. More specifically, taking into consideration the extracted peaks and the processing-time dependence on the size of the peak of the amorphous signal, the control device 90 is allowed to feed-back control the plasma doping processing conditions such as the high-frequency power to be applied by the plasma generating high-frequency power supply 5, the plasma doping processing time, the flow rate of the gas into the vacuum container 1, the pressure inside the vacuum container 1, or the like, so that a desired (set) crystal state can be accurately obtained. In this case, as one example of the feed-back control, in a case where the intensity of each of the extracted peaks is smaller than a desired intensity, the difference is calculated by the operation unit 29 so that the plasma doping processing time corresponding to the intensity of the calculated difference is calculated by the operation unit 29 according to the relationship between each of the extracted peaks and the processing-time dependence on the size of the peak of the amorphous signal, so that the doping processing time can be prolonged by the calculated plasma doping processing time. In a case where the plasma doping processing conditions are controlled during the feed-back control, the plasma doping processing time can be controlled most easily.

In the second embodiment, since the measuring region 9a having a depth of 20 μm or more from the surface of the process substrate 9 is measured so as to confirm changes in the impurity density and the crystal state of the surface of the process substrate 9 by the short-wavelength laser light beam 81B, the laser light beam 81A having a wavelength with a light absorption of 2 μm or more is used and applied to the process substrate 9. Then, the scattered light 82A from the process substrate 9 is detected by the detector 17 so that the detected light is used as reference light (reference signal).

With respect to a method for selecting the laser light beam 81A having a long light emission wavelength, in order to eliminate the influences by the impurity in the process substrate 9, a wavelength having an absorption coefficient of about 1000 times higher than the absorption coefficient of the measuring region 9a, that is, a wavelength having an absorption coefficient of 1/100 or less relative to the absorption coefficient of the short wavelength of the laser light beam 81B, is preferably selected. The reason therefor is described as follows. Since the SN ratio of the Raman scattered signal in a case of using the laser light beam 81A having a long light emission wavelength and the signal of the impurity and the amorphous signal generated in accordance with the plasma doping method are equivalent to each other, it is necessary to clearly distinguish these signals. As one actual example, in a case where the impurity depth is set to 20 nm, the light emission wavelength of the laser light beam 81A having the long light emission wavelength and generated by the long-wavelength laser oscillator 14A is 2 μm (4.8E⁻³ cm⁻¹), and as shown in FIG. 7, the light emission wavelength of the long-wavelength laser light beam 81A is preferably set to 621 nm or more. In this case, a He—Ne laser oscillator having a light emission wavelength of 633 nm is selected and used as the long-wavelength laser oscillator 14A.

For example, by monitoring the laser light beam 81B having the long light emission wavelength using the monitoring device 80, it becomes possible to monitor variable factors during the discharging process. By removing peaks of the Raman spectrum of the laser light beam 81B with the short wavelength and the single crystal silicon from the spectrum of the laser light beam 81B using the operation unit 29, it is possible to obtain a more accurate Raman scattered spectrum on the outermost portion of the surface of the process substrate 9.

In a method for taking out only the reference signal, by generating a pulse having a frequency different from that of the pulse generated in the short-wavelength laser oscillator 14B, it is possible to separate the signals from each other even in a case of using the detector 17 that is the same as the detector 17 for the laser light beam 81B with a short wavelength. It is required to use the pulse frequency of other than the laser light emission wavelength of the laser light 81B with a short wavelength, the frequency of the plasma generating high-frequency power supply 5, the power frequency supplied in an area where the plasma doping apparatus is used (60 Hz in the western area of Japan and the United States), transmission frequencies of apparatuses used in the plasma doping apparatus, and the pulse frequency of the short-wavelength laser oscillator 14B.

The operation unit 29 is allowed to detect a change in peak in the wavelength appearing in the graph of the Raman shift and the intensity, and upon detection of a predetermined amount of change by the operation unit 29, the control device 90 is allowed to change the high-frequency power of the plasma generating high-frequency power supply 5 applied to the coil 8, the processing time, or the high-frequency power of the high-frequency power applying high-frequency power supply 10 applied to the sample electrode 6.

For example, upon detection of an appearance of a peak of 470 cm⁻¹ indicating the peak of amorphous silicon using the operation unit 29, the absorption depth is computed by the operation unit 29 according to the ratio between the intensity of 470 cm⁻¹ representing the peak of the amorphous silicon and the intensity of 521 cm⁻¹ representing the peak of only the single crystal of silicon (peak of crystal silicon). Upon determination by the comparison determination unit 30 that the peak ratio is increasing with an intensity equal to or exceeding a set value, the control device 90 can control the high-frequency power applying high-frequency power supply 10 in order to decrease the high-frequency power being applied to the process substrate 9 from the high-frequency power applying high-frequency power supply 10 through the sample electrode 6, so as not to allow the amorphous layer to further proceed to a deeper region in the process substrate 9. Upon determination by the comparison determination unit 30 that the ratio of the intensity of 470 cm⁻¹ and the intensity of 521 cm⁻¹ has reached an intensity of not less than the certain set value, the control device 90 stops the plasma generating high-frequency power supply 5 and the high-frequency power applying high-frequency power supply 10 so as to stop the discharging time.

As shown in FIG. 10, in order to prevent a false-operation due to fluctuations in plasma discharging, by detecting the scattered light 82A in the region 9g at a sufficient depth from the surface of the process substrate 9 (such as a depth exceeding 100 nm from the surface plasma doping layer of the process substrate 9) using the detection optical system 85, fluctuations in plasma discharging are monitored so that values corresponding to the fluctuations are accumulated to the spectrum value of the plasma doping layer by the operation unit 29. The region 9g at the sufficient depth from the surface of the process substrate 9 has a light absorption coefficient of 100 nm or less, with a laser wavelength in this case being set to 420 nm to 1100 nm. The laser wavelength exceeding 1100 nm is not applicable because such a wavelength is transmitted through the silicon substrate.

The reference signal may be alternatively used as follows. Using the scattered light 82A in the sufficiently deep region 9g, crystal information (signal representing the crystal state) on the scattered light 82A is removed by the operation unit 29, so that the spectra representing only the amorphous state and the doping state during the plasma doping process can be computed by the operation unit 29.

Referring to a flow chart of FIG. 11B, the following description will discuss a plasma doping method using the plasma doping apparatus according to the second embodiment. The following operations can be basically carried out under control of the control device 90. As the detection of the impurity density is carried out similarly to the flow chart of the first embodiment, only the detection of the crystal state is described in the following description.

First in step S11, after the process substrate 9 is placed on the sample electrode 6, with a predetermined gas being supplied into the vacuum container 1 from the gas supply device 2 through the gas supply inlet 11 on the side wall of the vacuum container 1 under control of the control device 90, an evacuation process in the vacuum container 1 is carried out through the exhaust outlet 12 on the bottom face of the vacuum container 1 using the turbo molecular pump 3, so that the inside of the vacuum container 1 is maintained at a predetermined pressure by the pressure-adjusting valve 4 for opening and closing the exhaust outlet 12.

In step S12, under control of the control device 90, the laser light beams 81A and 81B emitted from the laser oscillators 14A and 14B are refracted downward respectively by the wavelength separating plate 19, and is allowed to pass through the dielectric window 7, while being condensed by the condensing lens 15, so as to be applied to the process substrate 9 in the vacuum container 1. The scattered light 82A and 82B emitted from the measuring region 9a of the process substrate 9 irradiated with the laser light beams 81A and 81B respectively are allowed to pass through the dielectric window 7, are transmitted through the condensing lens 15 and the wavelength separating plate 19, and are wavelength-separated by the prism or the diffraction grating of the spectroscope 16. The light, wavelength separated by the spectroscope 16, is detected by the detector 17 for every wavelength. The scattered light 82A is used as a reference signal, and the difference between the scattered light 82A and the scattered light 82B is obtained by the operation unit 29, so that a Raman intensity indicating the intensity of the amorphous signal is obtained by the operation unit 29. The intensity of the amorphous signal obtained by the operation unit 29 is temporarily stored in the comparison determination unit 30 as the intensity of the amorphous signal prior to the start of discharging.

In step S13, under control of the control device 90, a high-frequency power of 13.56 MHz, as one example, is supplied to the coil 8 from the plasma generating high-frequency power supply 5 so that an inductive coupling type plasma is generated in a space above the sample electrode 6 of the vacuum container 1 inside the vacuum container 1 as well as on the periphery thereof. In this case, the high-frequency power applying high-frequency power supply 10 is driven and controlled by the control device 90, and the electric potential of the sample electrode 6 is controlled, so that the process substrate 9 is allowed to have a negative electric potential relative to the plasma. In this way, the plasma doping process is started.

In step S14, the scattered light 82A and 82B emitted from the measuring region 9a of the process substrate 9 irradiated with the laser light beams 81A and 81B are allowed to pass through the dielectric window 7, are transmitted through the condensing lens 15 and the wavelength separating plate 19, and are wavelength-separated by the prism or the diffraction grating of the spectroscope 16. The light, wavelength-separated by the spectroscope 16, is detected by the detector 17 for every wavelength, and based on the detection results, the difference between the scattered light 82A and the scattered light 82B is obtained by the operation unit 29, so that a Raman intensity indicating the intensity of the amorphous signal is obtained by the operation unit 29. It is determined by the comparison determination unit 30 whether or not the intensity of the amorphous signal obtained by the operation unit 29 is not less than ten times higher than the intensity of the amorphous signal prior to the start of discharging as being temporarily stored in step S12. The process does not proceed to the next step but the doping process is continuously carried out until the intensity of the amorphous signal obtained in step S14 becomes not less than ten times higher than the intensity of the amorphous signal prior to the start of discharging as being temporarily stored in step S12. When the intensity of the amorphous signal obtained in step S14 becomes not less than ten times higher than the intensity of the amorphous signal prior to the start of discharging as being temporarily stored in step S12, the process proceeds to step S15 since a desired (set) non-crystallized state has been obtained.

In step S15, under control of the control device 90, the plasma generating high-frequency power supply 5 and the high-frequency power applying high-frequency power supply 10 are turned off to complete the plasma discharging, so as to complete the plasma doping process.

In one actual example, in the gas-supplying and exhausting processes in step S1, the pressure is set to 3 Pa, the He flow rate is set to 7 sccm, the B₂H₆ flow rate is set to 3 sccm, (V·p/Q) is set to 6.7 s, the exhausting operation is turned on, and the high-frequency power (ICP/BIAS) is set to 0/0 (W). Next, in the laser irradiation process in step S2, the pressure is set to 3 Pa, the He flow rate is set to 7 sccm, the B₂H₆ flow rate is set to 3 sccm, (V·p/Q) is set to 6.7 s, the exhausting operation is turned on, and the high-frequency power (ICP/BIAS) (that is, the high-frequency power from the plasma generating high-frequency power supply 5/the high-frequency power from the high-frequency power applying high-frequency power supply 10) is set to 800/200 (W). It is supposed that the volume of the vacuum chamber of the vacuum container 9 is set to V (L: Litter), the pressure inside the vacuum container 9 is set to p (Torr), and the flow rate of the supplied gas is set to Q (Torr·L/s).

In accordance with the second embodiment described above, by directly monitoring the outermost portion of the surface of the process substrate 9, the impurity density and the crystal state at a depth of 5 nm to 100 nm from the surface of the process substrate 9 can be more accurately measured in real time during the plasma doping process, so that, based upon the measurement results, the plasma doping processing conditions such as the high-frequency power to be applied by the plasma generating high-frequency power supply 5, the plasma doping processing time, the flow rate of the gas into the vacuum container 1, the pressure inside the vacuum container 1, or the like can be correctly feed-back controlled by the control device 90. Thus, the impurity density and the crystal state are correctly controlled so that the desired (set) impurity density and crystal state can be accurately obtained. Since the outermost portion of the surface of the process substrate 9 is directly monitored, the amount of the impurity discharged from the wall of the vacuum container 1 can also be taken into consideration, realizing more accurate control.

In the above-mentioned various embodiments of the present invention, within the applicable range of the present invention, exemplified are only a part of many variations relating to the shape of the vacuum container (vacuum chamber) 1, the system and the arrangement of the plasma generating high-frequency power supply 5, and the like. It is granted that, upon application of the present invention, various modifications other than those exemplified above may be made therein.

For example, not limited to a three-dimensional cone shape, the coil 8 may be formed in a plane shape, and a helicon wave plasma source, a magnetic neutral loop plasma source, a microwave plasma source with electric field (electron cyclotron resonance plasma source), or a parallel flat-plate type plasma source may be alternatively used.

In place of the helium gas, what may be used is an inert gas other than helium, namely, at least one gas selected from the group consisting of neon, argon, krypton, and xenon (zenon). These inert gases are advantageous of giving less adverse effects to the sample in comparison with other gases.

Exemplified above is a case where the sample 9 is prepared as a semiconductor substrate made of silicon. Alternatively, the present invention may be applied upon processing samples made of other various materials.

While boron has been exemplified as the impurity, in a case where the sample is prepared as a semiconductor substrate made of silicon, the present invention is effectively applicable particularly when the impurity is arsenic, phosphorus, boron, aluminum, or antimony. This is because these materials allow a shallow junction formed in the transistor portion.

Exemplified is the case where the sample is irradiated with the laser light beam during the plasma discharging process. However, the sample may be irradiated with the laser light beam even when no plasma is being discharged.

The present invention is effectively used in a case of a low doping density, in particular, when the plasma doping method and apparatus aim at a density in a range of from 1×10¹¹/cm² to 1×10¹⁷/cm². Moreover, the present invention provides superior effects as plasma doping method and apparatus that aim at a density in a range of from 1×10¹¹/cm² to 1×10¹⁴/cm². In a case where the doping density is larger than 1×10¹⁷/cm², a conventional ion implanting process may be used, while the conventional method has failed to deal with a device that requires a doping density of 1×10¹⁷/cm² or less. However, the present invention is applicable to even such a case.

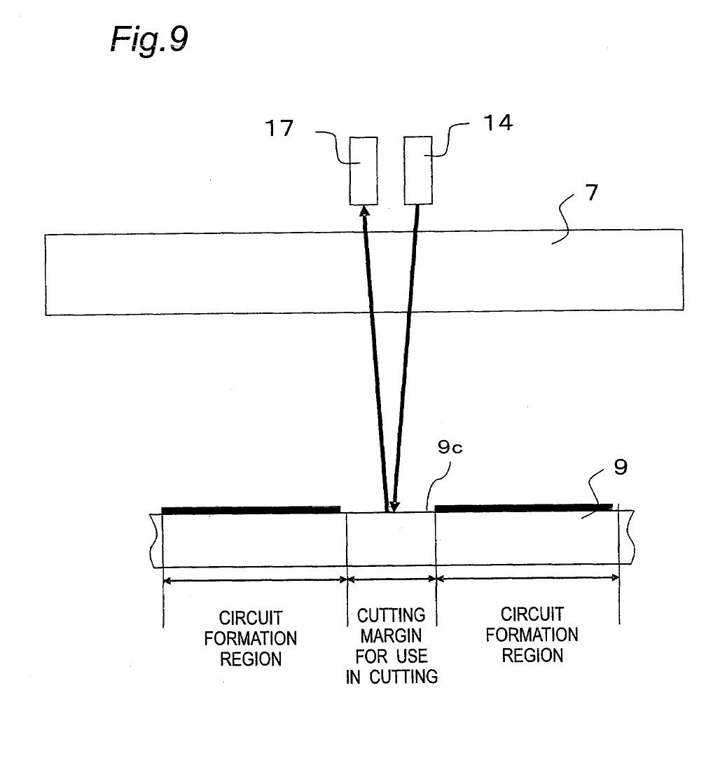

Normally, a pattern coated with resist is present in the process substrate 9, with the result that a signal derived from the resist is detected mixedly with the impurity signal and the amorphous layer signal. Therefore, an arbitrary detection pattern is provided in a space 9c (such as a scribe line region, that is, a cutting margin for use in cutting) used for cutting the semiconductor substrate, as shown in FIG. 9, so as to prevent signals other than the signal of the process substrate, the impurity signal, and the amorphous layer signal from being mixed therein.

The laser light beam 81 of the first embodiment or the first laser light beam 81B of the second embodiment is exemplified by the laser light beam having the laser wavelength with an absorption coefficient in the range of from 5 to 100 nm. However, the present invention is not limited thereto, but a laser light beam with an absorption coefficient in a range of from 5 nm to 100 nm corresponding to the thickness of the plasma doping layer formed in the process substrate 9, with a laser wavelength in a range of from 190 nm to 420 nm, may also be used. The reason for setting to 190 nm to 420 nm is because an excimer layer can be applied within this range.

In a case where the process substrate 9 is large and measurements are desirably carried out at a plurality of measuring points, a plurality of monitoring devices 80 may be installed so that the impurity density, or the impurity density as well as the crystal state may be detected using each of the monitoring devices 80 on the respective measuring points to carry out feed-back control.

Among the above-mentioned various embodiments, by appropriately combining arbitrary embodiments with one another, it is possible to obtain the respective effects.

The plasma doping method and apparatus according to the present invention realize improvement in stability of processes relating to the doping density and the like, and can be used in applications to an impurity doping process for a semiconductor, a manufacturing process for a thin-film transistor to be used in a liquid crystal, or surface modifying processes for various kinds of materials. Moreover, they are applicable also to an annealing device to be used in recovering the crystallinity as well as in activating an impurity.

By properly combining the arbitrary embodiments of the aforementioned various embodiments, the effects possessed by the embodiments can be produced.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A plasma doping method comprising: placing a substrate on an electrode in a vacuum chamber; supplying a dopant gas into the vacuum chamber and controlling an inside of the vacuum chamber to a certain fixed pressure so that a plasma is generated therein; and applying a high-frequency power to the substrate and injecting a dopant into a surface of the substrate so that a plasma doping layer is formed, the method comprising:
during a plasma discharging process, to a first region for forming the plasma doping layer on the surface of the substrate, allowing a first laser light beam serving as exciting light with a wavelength corresponding to an light absorption exerted therein, to be made incident in a direction orthogonal to the surface of the substrate;
receiving first scattered light from the substrate at a detector;
spectrum-resolving the first scattered light received by the detector using a spectroscope;
computing the first scattered light at an operation unit based on a spectrum with unnecessary exciting wavelengths having been removed by spectrum division at the spectroscope, and computing an impurity density of the plasma doping layer on the surface of the substrate at the operation unit based on the computed first scattered light; and
while feed-back-controlling plasma processing conditions at a control device so as to allow the computed impurity density to be equal to a set impurity density, injecting the dopant into the surface of the substrate to form the plasma doping layer.

2. The plasma doping method according to claim 1, wherein a wavelength of an exciting laser light beam having an absorption coefficient corresponding to a thickness of 5 nm to 100 nm of the plasma doping layer to be formed in the substrate is used as the wavelength of the first laser light beam, with the wavelength of the first laser light beam to be used being set to 190 nm to 420 nm.

3. The plasma doping method according to claim 1, further comprising:
allowing a second laser light beam serving as exciting light, with a wavelength corresponding to an light absorption exerted therein and being larger than the wavelength of the first laser light beam, to be made incident into a second region deeper than the first region for forming the plasma doping layer on a substrate surface side, in a direction orthogonal to the surface of the substrate during the plasma discharging process;
receiving second scattered light from the substrate at a detector;
spectrum-resolving the second scattered light received by the detector, by a spectroscope,
computing the second scattered light at the operation unit based on a spectrum with unnecessary exciting wavelengths having been removed by spectrum division at the spectroscope, and computing a film property or film thickness of an amorphous layer near the surface of the substrate at the operation unit based on a difference between the computed second scattered light and the first scattered light; and
while controlling plasma processing conditions at the control device so as to allow the computed film property or film thickness of the amorphous layer to be equal to a set film property or film thickness of the amorphous layer, injecting the dopant into the surface of the substrate to form the plasma doping layer.

4. The plasma doping method according to claim 3, wherein the second laser light beam is used as reference light with a wavelength corresponding to an light absorption exerted in the second region having a depth exceeding 100 nm below the plasma doping layer on the surface of the substrate, with the wavelength of the second laser light beam to be used being set to 420 nm to 1100 nm.

5. The plasma doping method according to claim 3, wherein a wavelength having an absorption coefficient of 1/100 or less relative to an absorption coefficient of the first laser light beam is used as the wavelength of the second laser light beam.

6. The plasma doping method according to claim 1, wherein the laser light beam is applied onto a detection pattern within a scribe line of the substrate.

7. A plasma doping apparatus comprising:
a vacuum chamber;
an electrode placed in the vacuum chamber to allow a substrate to be mounted thereon;
a dopant gas supply device for supplying a dopant gas into the vacuum chamber;
a pressure control device for maintaining an inside of the vacuum chamber at a certain fixed pressure;
a plasma generating device for generating a plasma in the vacuum chamber;
a high-frequency power applying device for applying a high-frequency power to the substrate;
a first laser light beam outputting device for allowing, during a plasma discharging process, a first laser light beam serving as exciting light with a wavelength corresponding to an light absorption exerted therein, to be made incident into a first region for forming the plasma doping layer on a substrate surface side in a direction orthogonal to the surface of the substrate;
a detector for receiving first scattered light scattered from the substrate in a direction orthogonal to the surface of the substrate;
a spectroscope for spectrum-resolving the first scattered light received by the detector;
an operation unit for computing the first scattered light based on a spectrum with unnecessary exciting wavelengths having been removed by spectrum division at the spectroscope, as well as for computing an impurity density of the plasma doping layer on the surface of the substrate based on the computed first scattered light; and
a control device for feed-back controlling plasma processing conditions so as to allow the impurity density computed at the operation unit to be equal to a set impurity density.

8. The plasma doping apparatus according to claim 7, wherein a wavelength of an exciting laser light beam having an absorption coefficient corresponding to a thickness of 5 nm to 100 nm of the plasma doping layer to be formed in the substrate is used as the wavelength of the first laser light beam, with the wavelength of the first laser light beam to be used being set to 190 nm to 420 nm.

9. The plasma doping apparatus according to claim 7, further comprising:
a second laser light beam outputting device for allowing, a second laser light beam serving as exciting light with a wavelength corresponding to an light absorption exerted therein and being larger than the wavelength of the first laser light beam, to be made incident into a second region deeper than the first region for forming the plasma doping layer on a substrate surface side in a direction orthogonal to the surface of the substrate during the plasma discharging process, wherein
the detector receives second scattered light from the substrate,
the spectroscope spectrum-resolves the second scattered light received by the detector,
the operation unit computes the second scattered light based on a spectrum with unnecessary exciting wavelengths having been removed by spectrum division at the spectroscope, as well as computes a film property or film thickness of an amorphous layer near the surface of the substrate based on a difference between the computed second scattered light and the first scattered light, and
the control device controls plasma processing conditions so as to allow the computed film property or film thickness of the amorphous layer to be equal to a set film property or film thickness of the amorphous layer.

10. The plasma doping apparatus according to claim 9, wherein the second laser light beam is used as reference light with a wavelength corresponding to an light absorption exerted in the second region at a depth exceeding 100 nm below the plasma doping layer on the surface of the substrate, with the wavelength of the second laser light beam being set to 420 nm to 1100 nm.

11. The plasma doping apparatus according to claim 9, wherein the wavelength of the second laser light beam has an absorption coefficient of 1/100 or less relative to an absorption coefficient of the first laser light beam.

12. The plasma doping apparatus according to claim 10, wherein the second laser light beam is used as reference light with a wavelength corresponding to an light absorption exerted in the second region at a depth exceeding 100 nm below the plasma doping layer on the surface of the substrate, with the wavelength of the second laser light beam being set to 420 nm to 1100 nm.
